(19) United States
(12) Patent Application Publication
(10) Pub. No.: US 2013/0099248 A1
(43) Pub. Date: Apr. 25, 2013

(54) NITRIDE SEMICONDUCTOR LIGHT EMITTING DEVICE

(71) Applicant: SAMSUNG ELECTRONICS CO., LTD., Suwon-si (KR)

(72) Inventors: Bum Joon KIM, Seoul (KR); Sung Tae KIM, Seoul (KR); Young Sun KIM, Suwon (KR); Suk Ho YOON, Seoul (KR); Ki Sung KIM, Suwon (KR); Ho Chul LEE, Seongnam (KR)

(73) Assignee: SAMSUNG ELECTRONICS CO., LTD., Suwon-si (KR)

(21) Appl. No.: 13/655,250

(22) Filed: Oct. 18, 2012

(30) Foreign Application Priority Data
Oct. 19, 2011 (KR) 10-2011-0106865

(51) Int. Cl. H01L 33/32

(52) U.S. Cl. 257/76; 257/E33.025

(57) ABSTRACT

There is provided a nitride semiconductor light emitting device including an n-type nitride semiconductor layer, an active layer disposed on the n-type nitride semiconductor layer, and a p-type nitride semiconductor layer disposed on the active layer. One or more current diffusion layers are disposed on a surface of the n-type nitride semiconductor layer. The current diffusion layer(s) includes a material having greater band gap energy than that of a material forming the n-type nitride semiconductor layer so as to form a two-dimensional electron gas layer at an interface with the material forming the n-type nitride semiconductor layer.

### CROSS-REFERENCE TO RELATED APPLICATIONS

This application claims the priority to Korean Patent Application No. 10-2011-0106865, filed on Oct. 19, 2011 in the Korean Intellectual Property Office, the disclosure of which is incorporated herein by reference.

### TECHNICAL FIELD

The present application relates to a nitride semiconductor light emitting device.

### BACKGROUND

A light emitting diode (LED) is a semiconductor light emitting device which generates light through the recombination of electrons and holes using the characteristics of a p-n junction structure. That is, when a voltage is applied to a semiconductor formed of a specific element, electrons and the holes are recombined at a p-n junction. In this instance, a lower amount of energy than that generated when the electrons and the holes are separated is generated, so that light may be emitted due to a difference in the energy generated at the time of electron-hole recombination. Notably of late, much attention has been drawn to group III nitride semiconductors capable of emitting light having a short wavelength such as blue light.

Such an LED is operated by applying electrical signals to electrodes having different polarities, and a current may then tend to flow concentratively in a region in which the electrode is formed, or in a region having low resistance. Accordingly, as a current flow narrows, an operating voltage (Vf) of the light emitting device increases due to the narrow current flow, and further, the light emitting device is vulnerable to electrostatic discharge. To overcome this problem, several methods of improving a current diffusion function inside the light emitting device have been proposed in the related art.

One of these methods includes inducing current to flow in a lateral direction by disposing a current blocking layer inside a semiconductor layer. However, an additional process for inserting a heterogeneous substance, for example, a dielectric substance such as SiO₂, or the like into the nitride semiconductor is required, and problems may occur in terms of crystallinity. Alternatively, an undoped semiconductor layer may be interposed between n-type and p-type semiconductor layers, and this takes advantage of a phenomenon in which electron mobility is relatively increased in the undoped semiconductor layer. However, even when the undoped semiconductor layer is used, a substantial difference in electron mobility is not large, and therefore, a current dispersion effect may be insufficient.

A need therefore exists to provide a nitride semiconductor light emitting device in which current diffusion is improved to thereby improve light emitting efficiency.

### SUMMARY

An aspect of the present application provides a nitride semiconductor light emitting device in which current diffusion is improved in a horizontal direction, thereby improving light emitting efficiency.

According to an aspect of the present application, there is provided a nitride semiconductor light emitting device. The device includes an n-type nitride semiconductor layer, an active layer disposed on the n-type nitride semiconductor layer, a p-type nitride semiconductor layer disposed on the active layer, and current diffusion layers disposed on at least one of an inside and a surface of the n-type nitride semiconductor layer. The current diffusion layers are comprised of a material having greater band gap energy than that of a material forming the n-type nitride semiconductor layer so as to form a two-dimensional electron gas layer at an interface with the material forming the n-type nitride semiconductor layer.

The n-type nitride semiconductor layer may include n-GaN, and at least one of the current diffusion layers may be formed of AlₓGa₁₋ₓN (0<x≦1) to form an interface with the n-GaN.

The n-type nitride semiconductor layer may include n-GaN, and at least one of the current diffusion layers may be formed of AlₓIn_{y}Ga_{1-x-y}N (0<x≦1 and 0≦y<1) to form an interface with the n-GaN.

At least one of the current diffusion layers may be disposed on a bottom surface of the n-type nitride semiconductor layer.

The nitride semiconductor light emitting device may further include a buffer layer disposed on a bottom surface of the current diffusion layer that is disposed on the bottom surface of the n-type nitride semiconductor layer among the current diffusion layers.

The buffer layer may include an undoped nitride semiconductor layer.

The n-type nitride semiconductor layer may include a first layer, and a second layer disposed on the first layer and having a lower concentration of an n-type impurity than that of the first layer.

At least one of the current diffusion layers may be disposed between the first layer and the second layer.

At least one of the current diffusion layers may have a thickness of 20 nm or less.

At least one of the current diffusion layers may be doped with an n-type impurity.

According to another aspect of the present application, there is provided a nitride semiconductor light emitting device. The device includes an n-type nitride semiconductor layer, an active layer disposed on the n-type nitride semiconductor layer, a p-type nitride semiconductor layer disposed on the active layer, and a current diffusion layer disposed at least on a bottom surface of the n-type nitride semiconductor layer. The current diffusion layer is comprised of a material having greater band gap energy than that of a material forming the n-type nitride semiconductor layer so as to form a two-dimensional electron gas layer at an interface with the material forming the n-type nitride semiconductor layer.

The current diffusion layer may have a thickness of 20 nm or less.

The nitride semiconductor light emitting device may further include a buffer layer disposed on a bottom surface of the current diffusion layer.

The buffer layer may include an undoped nitride semiconductor layer.

The n-type nitride semiconductor layer may include n-GaN, and the current diffusion layer may be formed of AlₓGa₁₋ₓN (0<x≦1) to form an interface with the n-GaN.

The n-type nitride semiconductor layer may include n-GaN, and the current diffusion layer may be formed of AlₓIn_{y}Ga_{1-x-y}N (0<x≦1 and 0≦y<1) to form an interface with the n-GaN.

The current diffusion layer may be further provided inside the n-type nitride semiconductor layer.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The above and other aspects, features and other advantages of the present application will be more clearly understood from the following detailed description taken in conjunction with the accompanying drawing figures. The drawing figures depict one or more implementations in accord with the present teachings, by way of example only, not by way of limitation. In the figures, like reference numerals refer to the same or similar elements.

FIG. 1 is a schematic cross-sectional view illustrating a nitride semiconductor light emitting device according to an example of the present application;

FIG. 2 is a view illustrating a conduction band energy level at a heterojunction interface formed around a current diffusion layer in the nitride semiconductor light emitting device of FIG. 1;

FIG. 3 is a schematic cross-sectional view illustrating a nitride semiconductor light emitting device according to another example of the present application;

FIG. 4 is a view illustrating a heterojunction structure that can be adopted in a modification of the example of FIG. 3;

FIG. 5 is a graph illustrating changes in surface resistance in accordance with the number of current diffusion layers;

FIG. 6 is a graph illustrating changes in output power in accordance with the number of current diffusion layers; and

FIG. 7 is a schematic cross-sectional view illustrating a nitride semiconductor light emitting device according to another example of the present application.

### DETAILED DESCRIPTION

Examples of the present application will now be described in detail with reference to the accompanying drawings. In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and circuitry have been described at a relatively high-level, without detail, in order to avoid unnecessarily obscuring aspects of the present teachings

However, the examples of the present application may be modified in many different forms and the scope of the application should not be limited to the examples set forth herein. Rather, these examples are provided so that this disclosure will be thorough and complete, and will fully convey the concept of the application to those skilled in the art. In the drawings, the shapes and dimensions of elements may be exaggerated for clarity.

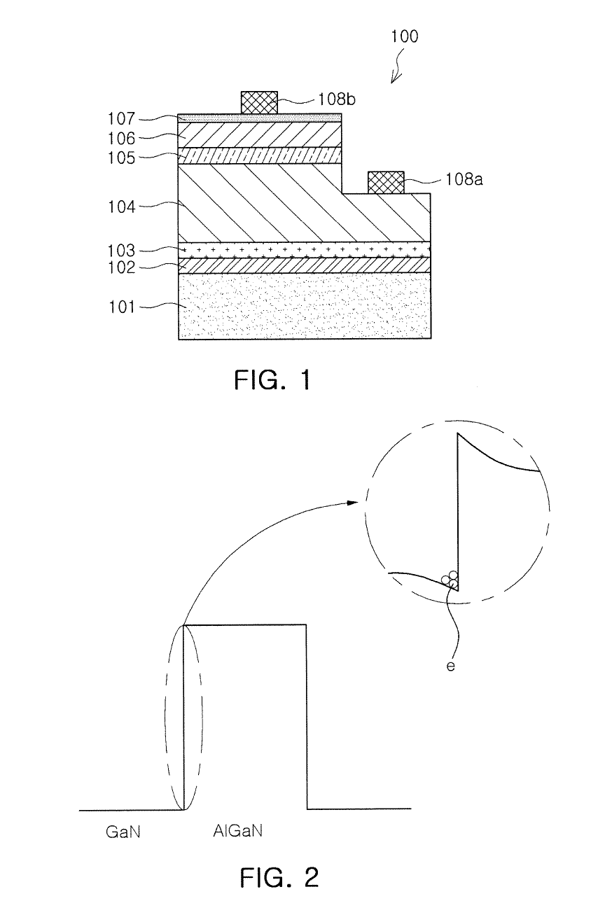

FIG. 1 is a schematic cross-sectional view illustrating a nitride semiconductor light emitting device according to an example of the present application, and FIG. 2 is a view illustrating a conduction band energy level at a heterojunction interface formed around a current diffusion layer in the nitride semiconductor light emitting device of FIG. 1.

Referring to FIG. 1, a nitride semiconductor light emitting device 100 according to the present example has a structure in which a light emitting structure is disposed on a substrate 101, and the light emitting structure includes an n-type nitride semiconductor layer 104, an active layer 105, and a p-type nitride semiconductor layer 106. In the present example, a current diffusion layer 103 is disposed on a bottom surface of the n-type nitride semiconductor layer 104, and the current diffusion layer 103 may form a two-dimensional electron gas (2DEG) layer with the n-type nitride semiconductor layer 104, thereby allowing for a uniform current flow distributed throughout a light emitting area.

A buffer layer 102 may be disposed on the substrate 101 before the light emitting structure is formed, and the buffer layer 102 may include an undoped nitride semiconductor layer, for example, an undoped GaN layer. However, the present application is not limited thereto, and the buffer layer 102 may be formed of an n-type nitride semiconductor. Further, the buffer layer 102 may be excluded according to some examples of the application. In addition, the buffer layer 102 may include a nucleation layer disposed on the substrate 101 in addition to the undoped nitride semiconductor layer. Meanwhile, as a structure for applying external electrical signals, an n-type electrode 108a is formed in a mesa etching region of the n-type nitride semiconductor layer 104, that is, a region exposed by removing part of the active layer 105 and the p-type nitride semiconductor layer 106, and an ohmic electrode layer 107 and a p-type electrode 108b may be disposed on the p-type nitride semiconductor layer 106. However, in the present application, terms such as “top”, “top surface”, “bottom”, “bottom surface”, and “lateral surface”, and the like are based on the accompanying drawings, and may be changed depending on a direction in which the semiconductor light emitting device is actually mounted.

The substrate 101 is provided for the growth of a nitride semiconductor single crystal, and a substrate formed of sapphire, Si, ZnO, GaAs, SiC, MgAl₂O₄, MgO, LiAlO₂, LiGaO₂, GaN, or the like may be used. Here, sapphire is a crystal having Hexa-Rhombo R3c symmetry and has a lattice constant of 13.001 Å along a C-axis and a lattice constant of 4.758 Å along an A-axis. Orientation planes of the sapphire include a C (0001) plane, an A (1120) plane, an R (1102) plane, and the like. Particularly, the C plane is mainly used as a substrate for nitride semiconductor growth because it relatively facilitates the growth of a nitride film and is stable at high temperatures.

The n-type and p-type nitride semiconductor layers 104 and 106 may be formed of a nitride semiconductor, for example, a material having a composition of AlₓIn_{y}Ga_{1-x-y}N (0≦x≦1, 0≦y≦1, 0≦x+y≦1), and each layer may be formed of a single layer, but formed of a plurality of layers having different characteristics in terms of a doping concentration, a composition, and the like. The active layer 105 disposed between the n-type and p-type nitride semiconductor layers 104 and 106 emits light having a predetermined amount of energy by the recombination of electrons and holes, and may have a multiquantum well (MQW) structure in which quantum well layers and quantum barrier layers are alternately stacked, for example, an InGaN/GaN structure. Meanwhile, the n-type and p-type nitride semiconductor layers 104 and 106 and the active layer 105 of the light emitting structure may be grown using a conventional process, such as metal organic chemical vapor deposition (MOCVD), hydride vapor phase epitaxy (HYPE), molecular beam epitaxy (MBE), and the like.

The ohmic electrode layer 107 may be made of a material having ohmic electrical characteristics with the p-type nitride semiconductor layer 106, and a transparent material or a light reflective material may be used as the ohmic electrode layer 107 in accordance with the intended use of the device 100. For example, the ohmic electrode layer 107 may be made of a transparent conductive oxide such as ITO, CIO, ZnO, or the like, having a superior ohmic-contact performance while maintaining a high level of light transmittance among materials for a transparent electrode. Alternatively, the ohmic electrode layer 107 may be made of a highly reflective material such as silver (Ag), aluminum (Al), or the like, and in this case, may be suitable for mounting the device 100 in a so-called flip chip manner. However, the ohmic electrode layer 107 is not required for the present example, and may be excluded according to varying circumstances.

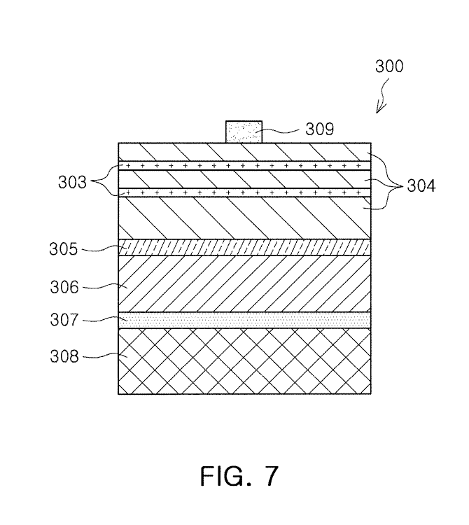

The n-type and p-type electrodes 108a and 108b may be formed by performing deposition, sputtering, or the like with respect to an electrical conductive material known in the art, for example, at least one material of silver (Ag), aluminum (Al), nickel (Ni), chromium (Cr), and the like. However, in a case of the structure shown in FIG. 1, the n-type and p-type electrodes 108a and 108b are disposed on respective top surfaces of the n-type nitride semiconductor layer 104 and the ohmic electrode layer 107, but such a formation method of the electrodes 108a and 108b is merely exemplary. The electrodes may be formed in various positions of the light emitting structure including the n-type nitride semiconductor layer 104, the active layer 105, and the p-type nitride semiconductor layer 106. For example, as shown in the example of FIG. 7, a surface of the p-type nitride semiconductor layer is exposed by removing the substrate without etching the light emitting structure, and then the electrode is disposed on the exposed surface.

According to the present example, the current diffusion layer 103 induces current to be evenly spread over the entirety of the light emitting surface, and for this, forms the 2DEG layer at an interface with the n-type nitride semiconductor layer 104. In this case, band gap energy of a material forming the current diffusion layer 103 is greater than that of a material forming the n-type nitride semiconductor layer 104. For example, when the n-type nitride semiconductor layer 104 includes n-GaN, the current diffusion layer 103 is formed of AlₓGa₁₋ₓN (0<x≦1), that is, AlGaN or AlN, thereby forming an interface with the n-GaN. In addition, the current diffusion layer 103 may contain an In component, that is, be formed of AlₓIn_{y}Ga_{1-x-y}N (0<x≦1, 0≦y<1), thereby forming the interface with the n-GaN. In this case, the current diffusion layer 103 may be doped with an n-type impurity so as to have superior electrical characteristics. In addition, the current diffusion layer 103 may have a thickness of 20 nm or less in consideration of conditions for forming the 2DEG layer, crystallinity, and the like; however, the present application is not limited thereto.

In this manner, when the n-type nitride semiconductor layer 104 and the current diffusion layer 103 form a heterojunction interface, carrier mobility is improved at the heterojunction interface, and therefore, current flow may be formed in a lateral direction. More specifically, referring to FIG. 2, at an interface between heterogeneous nitride semiconductor layers, for example, GaN and AlGaN layers, a well region is generated due to polarization, and carriers (e) confined in the well region have a relatively higher mobility. Accordingly, the hetero-junction interface such as GaN/AlGaN may be employed in the inside of the device, thereby securing high-level current diffusion characteristics.

Meanwhile, since the current diffusion characteristics may be changed in accordance with a position at which the hetero-junction interface is formed, the inventors of the present application applied the current diffusion layer in three different positions and examined a driving voltage and an output power.

As a first example I, a structure in which the current diffusion layer 103 is disposed on the bottom surface of the n-type nitride semiconductor layer 104 is provided. As a second example II, a structure in which the current diffusion layer 103 is inserted into the n-type nitride semiconductor layer 104 is provided. As a third example III, a structure in which the current diffusion layer 103 is disposed on a top surface of the n-type nitride semiconductor layer 104, that is, between the n-type nitride semiconductor layer 104 and the active layer 105 is provided. In this case, the current diffusion layer uses Al_{0.37}Ga_{0.63}N doped with an n-type impurity, and has a thickness of about 5 nm. In the above-described structures, a driving voltage and an output power are shown as below.

| | Driving Voltage (V) | Output Power (mW) |
|---|---|---|
| I | 3.22 | 131 |
| II | 3.22 | 128 |
| III | 4.11 | 126 |

Based on the experimental results above, it has been found that, when the current diffusion layer 103 was disposed on the bottom surface of the n-type nitride semiconductor layer 104 according to the present example, an improved amount of output power, while maintaining a low driving voltage was obtained.

Meanwhile, the number of current diffusion layers may also affect the characteristics of the device, in addition to the formation position of the current diffusion layer. In other words, as the number of current diffusion layers increases, current flow in the lateral direction may further increase; however, an increase in the number of heterojunction interfaces may adversely affect crystallinity, and the like of the semiconductor layer.

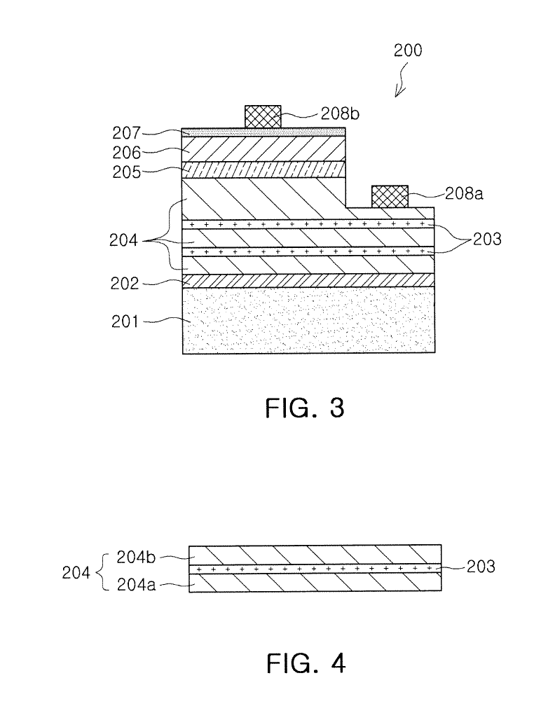

FIG. 3 is a schematic cross-sectional view illustrating a nitride semiconductor light emitting device according to another example of the present application, and FIG. 4 is a view illustrating a hetero-junction structure that can be adopted in a modification of the example of FIG. 3.

Referring to FIG. 3, in a manner similar to that of the above described example, a nitride semiconductor light emitting device 200 according to the present example includes a substrate 201, a buffer layer 202, a current diffusion layer 203, an n-type nitride semiconductor layer 204, an active layer 205, a p-type nitride semiconductor layer 206, an ohmic electrode layer 207, an n-type electrode 208a, and a p-type electrode 208b. In this case, the buffer layer 202 and the ohmic electrode layer 207 may be excluded according to some examples of the application.

In the present example, a plurality of current diffusion layers 203 are provided, and may be disposed on at least one of an inside and a surface of the n-type nitride semiconductor layer 204. FIG. 3 shows an example in which the current diffusion layer 203 is disposed on the inside of the n-type nitride semiconductor layer 204, but at least one of the current diffusion layers 203 may be disposed on at least one of a bottom surface and a top surface of the n-type nitride semiconductor layer 204. In addition, as shown in FIG. 4, the n-type nitride semiconductor layer 204 may include a first layer 204a having a relatively high concentration of an n-type impurity, and a second layer 204b formed above the first layer 204a and having a lower concentration of the n-type impurity than that of the first layer 204a. Here, at least one of the current diffusion layers 203 may be disposed between the first layer 204a and the second layer 204b.

The inventors of the present application examined changes in surface resistance and output power in accordance with the number of current diffusion layers, and the results thereof are described below. The inventors experimented a case in which the current diffusion layer was absent, and cases in which the number of current diffusion layers were 1, 2, and 4, and when a plurality of current diffusion layers were provided, the current diffusion layers were disposed to have identical intervals therebetween.

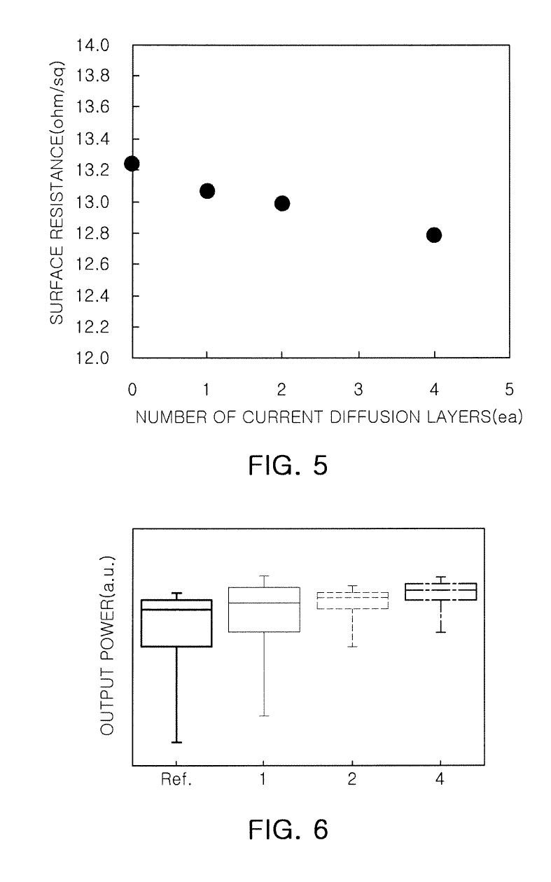

FIG. 5 is a graph illustrating changes in surface resistance in accordance with the number of current diffusion layers, and FIG. 6 is a graph illustrating changes in output power in accordance with the number of current diffusion layers.

First, referring to FIG. 5, it has been found that the surface resistance was reduced with an increase in the number of current diffusion layers. Accordingly, electrical characteristics of the device may be improved by adopting the plurality of current diffusion layers as in the present example.

Next, referring to FIG. 6, it has been found that the output power increased when the current diffusion layer was provided in comparison with when the current diffusion layer was absent (Ref.), and significantly increased as the number of current diffusion layers was increased. Based on the results, when a plurality of current diffusion layers are provided in an appropriate number considering processability, crystallinity, and the like (two or four current diffusion layers are provided in the present example), electrical characteristics and light emitting efficiency are improved.

FIG. 7 is a schematic cross-sectional view illustrating a nitride semiconductor light emitting device according to another example of the present application. In the present example, a nitride semiconductor light emitting device 300 has a structure in which a light emitting structure is disposed on a conductive substrate 308, and the light emitting structure includes an n-type nitride semiconductor layer 304, an active layer 305, and a p-type nitride semiconductor layer 306. A plurality of current diffusion layers 303 may be disposed on at least one of an inside and a surface of the n-type nitride semiconductor layer 304, and in a manner similar to that of the above-described examples, may form a 2DEG layer at an interface with the n-type nitride semiconductor layer 304 to thereby contribute to current distribution. However, in the present example, the current diffusion layers 303 are adopted based on the structure described in FIG. 3, but the structure of FIG. 1 may also be used.

An n-type electrode 309 may be disposed on a top surface of the n-type nitride semiconductor layer 304, and a reflective metal layer 307 and a conductive substrate 308 may be formed under the p-type nitride semiconductor layer 306. The reflective metal layer 307 may be made of a material showing electrical ohmic characteristics with the p-type nitride semiconductor layer 306, and further, may be made of a metal having high reflectivity so as to reflect light emitted from the active layer 305. In consideration of these functions, the reflective metal layer 307 may be made of a material such as silver (Ag), nickel (Ni), aluminum (Al), rhodium (Rh), palladium (Pd), iridium (Ir), ruthenium (Ru), magnesium (Mg), zinc (Zn), platinum (Pt), gold (Au), or the like. The conductive substrate 308 may be connected with an external power source to thereby apply electrical signals to the p-type nitride semiconductor layer 306.

The conductive substrate 308 may serve as a support to support the light emitting structure in a laser lift-off process and the like for removing a substrate used for semiconductor growth, and may be made of a material including any one of gold (Au), nickel (Ni), aluminum (Al), copper (Cu), tungsten (W), silicon (Si), selenium (Se), and GaAs, for example, a material doped with Al on an Si substrate. In this case, the conductive substrate 308 may be disposed on the reflective metal layer 307 by plating, sputtering, deposition, or the like. Alternatively, the conductive substrate 308 separately manufactured in advance may be bonded to the reflective metal layer 307 through a conductive bonding layer, or the like.

As set forth above, according to examples of the present application, a nitride semiconductor light emitting device, in which current diffusion in a horizontal direction may be improved, obtains enhanced light emitting efficiency.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A nitride semiconductor light emitting device, comprising:
an n-type nitride semiconductor layer;
an active layer disposed on the n-type nitride semiconductor layer;
a p-type nitride semiconductor layer disposed on the active layer; and
a plurality of current diffusion layers:
disposed on at least one of an inside and a surface of the n-type nitride semiconductor layer, and
comprised of a material having greater band gap energy than that of a material forming the n-type nitride semiconductor layer so as to form a two-dimensional electron gas layer at an interface with the material forming the n-type nitride semiconductor layer.

2. The nitride semiconductor light emitting device of claim 1, wherein:
the n-type nitride semiconductor layer includes n-GaN, and
at least one of the plurality of current diffusion layers is formed of AlₓGa₁₋ₓN (0<x≦1) to form an interface with the n-GaN.

3. The nitride semiconductor light emitting device of claim 1, wherein:
the n-type nitride semiconductor layer includes n-GaN, and
at least one of the plurality of current diffusion layers is formed of AlₓIn_{y}Ga_{1-x-y}N (0<x≦1 and 0≦y<1) to form an interface with the n-GaN.

4. The nitride semiconductor light emitting device of claim 1, wherein at least one of the plurality of current diffusion layers is disposed on a bottom surface of the n-type nitride semiconductor layer.

5. The nitride semiconductor light emitting device of claim 4, further comprising:
a buffer layer disposed on a bottom surface of the current diffusion layer that is disposed on the bottom surface of the n-type nitride semiconductor layer among the plurality of current diffusion layers.

6. The nitride semiconductor light emitting device of claim 5, wherein the buffer layer includes an undoped nitride semiconductor layer.

7. The nitride semiconductor light emitting device of claim 1, wherein the n-type nitride semiconductor layer includes:
a first layer, and
a second layer disposed on the first layer and having a lower concentration of an n-type impurity than that of the first layer.

8. The nitride semiconductor light emitting device of claim 7, wherein at least one of the plurality of current diffusion layers is disposed between the first layer and the second layer.

9. The nitride semiconductor light emitting device of claim 1, wherein at least one of the plurality of current diffusion layers has a thickness of 20 nm or less.

10. The nitride semiconductor light emitting device of claim 1, wherein at least one of the plurality of current diffusion layers is doped with an n-type impurity.

11. A nitride semiconductor light emitting device, comprising:
an n-type nitride semiconductor layer;
an active layer disposed on the n-type nitride semiconductor layer;
a p-type nitride semiconductor layer disposed on the active layer; and
a current diffusion layer:
disposed at least on a bottom surface of the n-type nitride semiconductor layer, and
comprised of a material having greater band gap energy than that of a material forming the n-type nitride semiconductor layer so as to form a two-dimensional electron gas layer at an interface with the material forming the n-type nitride semiconductor layer.

12. The nitride semiconductor light emitting device of claim 11, wherein the current diffusion layer has a thickness of 20 nm or less.

13. The nitride semiconductor light emitting device of claim 11, further comprising:
a buffer layer disposed on a bottom surface of the current diffusion layer.

14. The nitride semiconductor light emitting device of claim 13, wherein the buffer layer includes an undoped nitride semiconductor layer.

15. The nitride semiconductor light emitting device of claim 11, wherein:
the n-type nitride semiconductor layer includes n-GaN, and
the current diffusion layer is formed of AlₓGa₁₋ₓN (0<x≦1) to form an interface with the n-GaN.

16. The nitride semiconductor light emitting device of claim 11, wherein:
the n-type nitride semiconductor layer includes n-GaN, and
the current diffusion layer is formed of AlₓIn_{y}Ga_{1-x-y}N (0<x≦1 and 0≦y<1) to form an interface with the n-GaN.

17. The nitride semiconductor light emitting device of claim 11, wherein the current diffusion layer is provided inside the n-type nitride semiconductor layer.

18. The nitride semiconductor light emitting device of claim 11, further comprising:
an ohmic electrode layer disposed on the p-type nitride semiconductor layer.

19. The nitride semiconductor light emitting device of claim 18,
wherein the ohmic electrode layer disposed on a transparent conductive oxide.

20. The nitride semiconductor light emitting device of claim 1, further comprising:
a reflective metal layer disposed on the p-type nitride semiconductor layer.
